(19) United States
(12) Patent Application Publication
(10) Pub. No.: US 2008/0124885 A1
(43) Pub. Date: May 29, 2008

(54) METHOD OF FABRICATING CAPACITOR AND ELECTRODE THEREOF

(75) Inventors: Tsung-De Lin, Taichung City (TW); Cheng-Che Lee, Taichung County (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, omitted

(73) Assignee: PROMOS TECHNOLOGIES INC., Hsinchu (TW)

(21) Appl. No.: 11/624,219

(22) Filed: Jan. 18, 2007

(30) Foreign Application Priority Data
Nov. 28, 2006 (TW) 95143934

(51) Int. Cl. H01L 21/768; H01L 21/62

(52) U.S. Cl. 438/386; 438/672; 257/E21.586; 257/E21.577; 257/E21.52

(57) ABSTRACT

A method of fabricating an electrode of a capacitor is provided. A substrate is provided and a dielectric layer is then formed thereon. After that, one multilayer mask is formed on the dielectric layer to expose a portion of the dielectric layer, wherein the multilayer mask consists of at least two layers of materials having different etching rates respectively. The exposed dielectric layer is removed to form a trench, and then the dielectric layer is over-etched, so as to widen the inside diameter of the trench. Thereafter, a conductive layer is formed on the substrate, and thus the multilayer mask and a surface of the trench are covered with the conductive layer. The conductive layer except that in the trench is then removed so as to form the electrode of the capacitor. Therefore, it can prevent the conductive layer from generating more loss.

### CROSS-REFERENCE TO RELATED APPLICATION

This application claims the priority benefit of Taiwan application serial no. 95143934, filed on Nov. 28, 2006. All disclosure of the Taiwan application is incorporated herein by reference.

### BACKGROUND OF THE INVENTION

1. Field of the Invention

The present invention relates to a capacitor process. More particularly, the present invention relates to a method of fabricating a capacitor and an electrode thereof.

2. Description of Related Art

Semiconductor memory devices usually need capacitors to make each memory such as a dynamic random access memory (DRAM) storing binary data according to a bias degree of the capacitor. The charges stored in the capacitor are a basic memory characteristic of the DRAM. The charge storage of the capacitor depends on the capacitance of the capacitor, and the capacitance is determined according to the area of a storage electrode, an isolation reliability between an upper electrode and a lower electrode of the capacitor, and a dielectric constant of the dielectric.

FIG. 1 is a schematic cross-sectional view of a conventional lower electrode of a capacitor.

Referring to FIG. 1, when the lower electrode of the capacitor is fabricated in general, a thick dielectric layer 106 is deposited on an inner dielectric layer 104 having a contact 102 and formed on a substrate 100, and then a trench 108 is formed in the dielectric layer 106. Next, a polysilicon layer 110 is deposited on the entire substrate 100 and a surface of the trench 108 to serve as the lower electrode. Then, a photoresist 112 is filled in the trench 108, and the polysilicon layer 110 is etched back through the blocking of the photoresist 112.

However, in the method of fabricating the lower electrode of the capacitor provided in the conventional art, the photoresist 112 after being filled in the trench 108 may be slightly depressed (as shown in FIG. 1), such that the polysilicon layer 110 along the edge of the trench 108 has a loss portion 114 as shown in FIG. 1, resulting in a decrease of the area of the lower electrode of the capacitor and reducing the capacitance of the capacitor.

### SUMMARY OF THE INVENTION

Accordingly, the present invention is directed to a method of fabricating an electrode of a capacitor, so as to overcome the loss of the electrode of the capacitor.

The present invention is also directed to a method of fabricating the capacitor, so as to prevent the decrease of the capacitance of the capacitor.

The present invention provides a method of fabricating the electrode of the capacitor. Firstly, a substrate is provided, and a dielectric layer is formed on the substrate. Then, a multilayer mask is formed on the dielectric layer, a portion of the dielectric layer is exposed, and the multilayer mask consists of at least two layers of materials with different etching rates. Next, the exposed dielectric layer is removed to form a trench, and the dielectric layer is over-etched so as to widen the inside diameter of the trench. Then, a conductive layer is formed on the substrate to cover the multilayer mask and a surface of the trench, and the conductive layer except that in the trench is removed, so as to form the electrode of the capacitor.

In an embodiment of the present invention, the step of forming the multilayer mask on the dielectric layer comprises forming a silicon nitride layer on the dielectric layer, forming a polysilicon mask on the silicon nitride layer, and then transferring a pattern of the polysilicon mask to the silicon nitride layer. In addition, the step of over-etching the dielectric layer comprises cleaning the residual polysilicon mask at the same time.

In an embodiment of the present invention, the process of over-etching the dielectric layer comprises wet etching.

In an embodiment of the present invention, the step of removing the conductive layer except that in the trench comprises filling a photoresist layer in the trench, and etching back the conductive layer. In addition, after the conductive layer except that in the trench is removed, the photoresist layer is removed.

In an embodiment of the present invention, the material of the conductive layer is selected from among polysilicon, hemi-spherical silicon grain (HSG), metal, and a nitride thereof.

The present invention further provides a method of fabricating the capacitor. Firstly, a substrate with a contact is provided, and a dielectric layer is formed on the substrate. Next, a multilayer mask is formed on the dielectric layer, a portion of the dielectric layer is exposed, and the multilayer mask consists of at least two layers of materials with different etching rates. Then, the exposed dielectric layer is removed, so as to form a trench and expose the contact, and then the dielectric layer is over-etched, so as to widen the inside diameter of the trench, and the etching rate of the dielectric layer is higher than the etching rate of the multilayer mask. Next, a layer of first electrode is formed on the surface of the trench, a capacitor dielectric layer is formed on the first electrode, and finally a second electrode is formed on the capacitor dielectric layer.

In an embodiment of the present invention, the step of forming the multilayer mask on the dielectric layer comprises forming a silicon nitride layer on the dielectric layer, forming a polysilicon mask on the silicon nitride layer, and finally transferring a pattern of the polysilicon mask to the silicon nitride layer. Moreover, when the dielectric layer is over-etched, the residual polysilicon mask is cleaned.

In an embodiment of the present invention, the process of over-etching the dielectric layer comprises wet etching.

In an embodiment of the present invention, the step of forming the first electrode on the surface of the trench comprises forming a conductive layer on the substrate to cover the multilayer mask and the surface of the trench, filling a photoresist layer in the trench, and then etching back the conductive layer. Then, the photoresist layer is removed.

In an embodiment of the present invention, the contact is a storage node contact (SNC).

In an embodiment of the present invention, the material of the first electrode is one selected from among polysilicon, HSG, metal, and a nitride thereof.

In an embodiment of the present invention, the material of the capacitor dielectric layer comprises SiO₂, Si₃N₄, Ta₂O₅, HfO₂, HfON, ZrO₂, CeO₂, TiO₂, Y₂O₃, Al₂O₃, La₂O₅, SrTiO₃, BST, or PZT.

In an embodiment of the present invention, the material of the second electrode is one selected from among polysilicon, AlCu, metal, and a nitride thereof.

In an embodiment of the present invention, after the capacitor dielectric layer is formed and before the second electrode is formed, the method further comprises forming an intermediate layer on the surface of the capacitor dielectric layer, in which the intermediate layer comprises one of the group consisting of TiN, TaN, Ti, and Ta.

In the present invention, the multilayer mask is used as the mask when the trench is formed by etching, and a step of widening the trench is added when the trench is formed, thus preventing the over-loss of the lower electrode and the decrease of the capacitance of the capacitor.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a portion of this specification. The drawings illustrate embodiments of the invention and, together with the description, serve to explain the principles of the invention.

FIG. 1 is a schematic cross-sectional view of a conventional lower electrode of a capacitor.

FIGS. 2A to 2H are schematic cross-sectional views of the fabricating flow of an electrode of a capacitor according to an embodiment of the present invention.

FIG. 2I is a schematic cross-sectional view of fabricating the capacitor after the formation of the electrode of FIG. 2H.

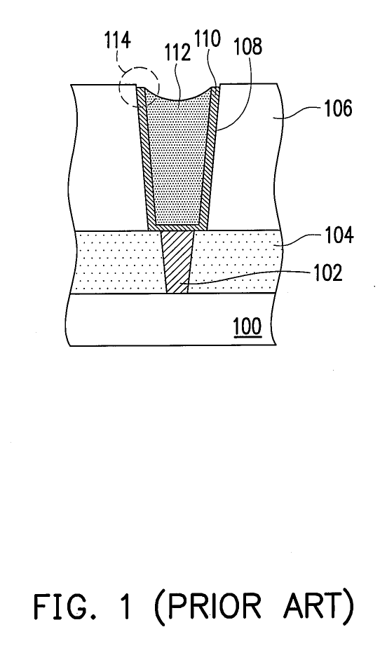

### DESCRIPTION OF EMBODIMENTS

The embodiments of the present invention are further described with the accompanying drawings below. However, the present invention may be implemented by different forms, and will not be limited by the embodiments illustrated in the specification. In the drawings, in order to apparently indicate the sizes of each layer and region, the layers and regions are magnified and not sized.

Moreover, the wording used in the specification is used to describe a practical embodiment below, and is not intended to limit the present invention. As used herein, the singular forms “a” and “an” are intended to include the plural forms as well, unless the context clearly indicates otherwise.

As used herein, “First” and “second” etc. are intended to discriminate a certain region, layer, or portion from another region, layer, or portion.

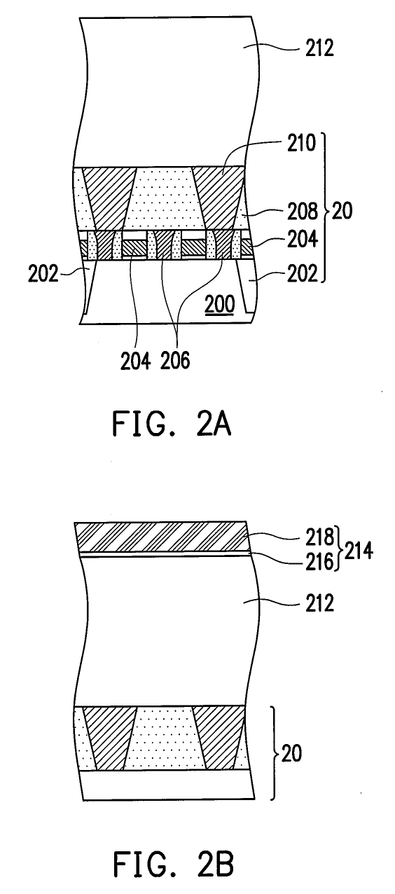

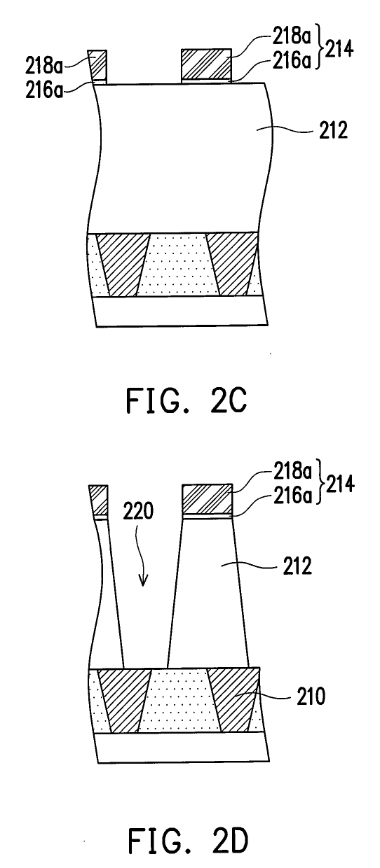

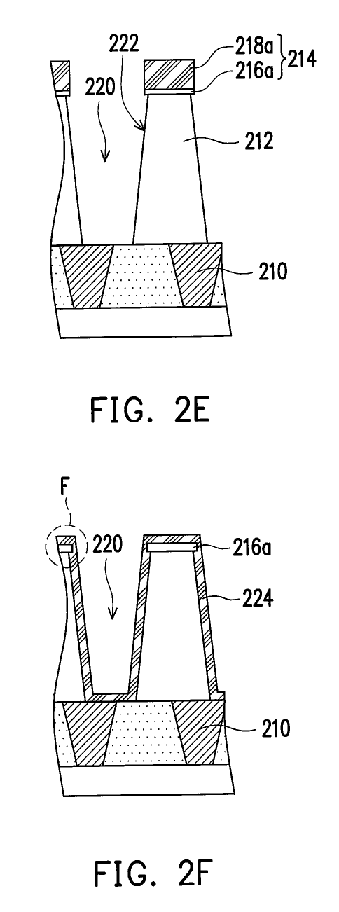

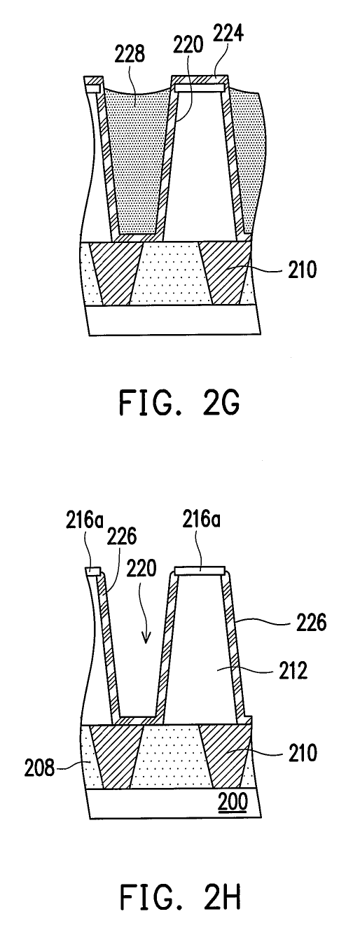

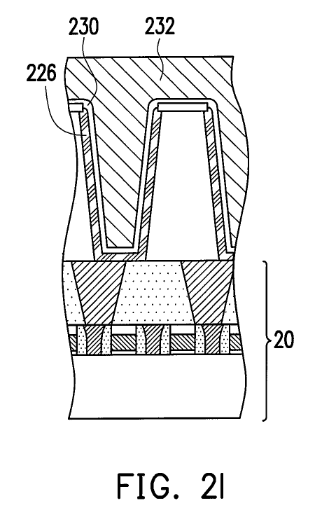

FIGS. 2A to 2H are schematic cross-sectional views of the fabricating flow of an electrode of a capacitor according to an embodiment of the present invention.

Referring to FIG. 2A, firstly a substrate 20 is provided. When a capacitor over bit line (COB) is taken as an example in this embodiment, the substrate 20 includes at least a wafer 200, isolation structures 202 in the wafer 200, bit line structures 204 on the wafer 200, a landing plug contact (LPC) 206 between the bit line structures 204, inner dielectric layers 208 on the bit line structures 204, and contacts 210 in the inner dielectric layers 208. The contact 210 is used as a storage node contact (SNC). Next, a dielectric layer 212 is formed on the substrate 20, and the dielectric layer 212 is, for example, formed by a PSG base and an oxide top layer with a tetraethyl orthosilicate (TEOS) as a deposition gas source.

In order to illustrate clearly, in the subsequent, the components under the inner dielectric layer 208 are omitted from the following drawing. Referring to FIG. 2B, a multilayer mask 214 is formed on the dielectric layer 212, a portion of the dielectric layer 212 is exposed, and the multilayer mask 214 consists of at least two layers of materials with different etching rates. For example, in the step of forming the multilayer mask 214, firstly a silicon nitride layer 216 is formed on the dielectric layer 212, and a polysilicon mask 218 is formed on the silicon nitride layer 216. Definitely, in addition to that used in this embodiment, other materials may also be used to form the multilayer mask 214, and the number of the layers may be more than two, which will not be limited to this embodiment.

Next, referring to FIG. 2C, the pattern of the polysilicon mask 218a is transferred to the silicon nitride layer 216a. As the etching selection ratios of the polysilicon mask 218a and the dielectric layer 212 are large, the multilayer mask 214 is suitable to be used as the mask for etching the dielectric layer 212.

Then, referring to FIG. 2D, the exposed dielectric layer 212 is removed to form the trench 220, and the contact 210 is exposed. Here, due to a long-time etching, the polysilicon mask 218a at the upper portion of the multilayer mask 214 is etched.

Next, referring to FIG. 2E, the dielectric layer 212 is over-etched, so as to widen the inside diameter 222 of the trench 220. The step of over-etching the dielectric layer 212 is for example performed by a wet etching process. When the multilayer mask 214 has the conductive polysilicon material, the step of cleaning the residual polysilicon mask 218a is required, such that a buffer oxidation etchant (BOE) of HF and NH₄F can be used to perform wet etching. In addition, during over-etching, as the etching rate of the dielectric layer 212 is higher than the etching rate of the multilayer mask 214, an inner tangency situation in the trench 220 occurs.

Then, referring to FIG. 2F, a conductive layer 224 is formed on the substrate 20 to cover the multilayer mask (only the silicon nitride layer 216a is remained under this situation) and the surface of the trench 220. As the silicon nitride layer 216a exists at the portion F, a portion of the conductive layer 224 is shielded. The material of the conductive layer 224 is one selected from among polysilicon, HSG, metal, and a nitride thereof, for example, Ta, W, Ti, TaN, Ta—Si—N, TiN, WN, Ti—Si—N, or W—Si—N.

Then, referring to FIG. 2G, in order to remove the conductive layer 224 except that in the trench 220, a photoresist layer 228 is first filled in the trench 220, and the conductive layer 224 except that in the trench 220 is exposed.

Next, referring to FIG. 2H, the conductive layer 224 is etched back (as shown in FIG. 2G), so as to form the first electrode 226 of the capacitor. Then, the photoresist layer 228 (as shown in FIG. 2G) is removed. In this embodiment, the silicon nitride layer 216a is used as a material layer in the multilayer mask 224, so the silicon nitride layer 216a may shield the first electrode 226 beneath, so as to prevent the over-loss and function as an etching stop layer.

Then, FIG. 2I is a schematic cross-sectional view of fabricating a capacitor of the present invention after finishing the first electrode of FIG. 2H, and the substrate 20 is identical to that shown in FIG. 2A.

Referring to FIG. 2I, after the first electrode 226 is formed, a capacitor dielectric layer 230 is formed on the first electrode 226, and the material of the capacitor dielectric layer 230 is for example SiO₂, Si₃N₄, Ta₂O₅, HfO₂, HfON, ZrO₂, CeO₂, TiO₂, Y₂O₃, Al₂O₃, La₂O₅, SrTiO₃, BST(BaₓSr₁₋ₓTiO₃, 0≦x≦1), or PZT (PbZrₓTi₁₋ₓO₃, 0≦x≦1). Then, the second electrode 232 is formed on the capacitor dielectric layer 230, the material is one selected from among polysilicon, AlCu, metal, and a nitride thereof, such as Ti, TiN, Ta, TaN, and Al. Moreover, although it is not shown in the figure, after the capacitor dielectric layer 230 is formed and before the second electrode 232 is formed, an intermediate layer (not shown) is formed on the surface of the capacitor dielectric layer, and the intermediate layer is selected from a group consisting of TiN, TaN, Ti, and Ta.

To sum up, in the present invention, the multilayer mask is used as the mask when the trench is formed by etching, thereby preventing the over-loss of the lower electrode and the decrease of the capacitance of the capacitor. In addition, the step of widening the trench performed when the trench is formed can also shorten the distance between the trenches.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A method of fabricating an electrode of a capacitor, comprising:
providing a substrate;
forming a dielectric layer on the substrate;
forming a multilayer mask on the dielectric layer, and exposing a portion of the dielectric layer, wherein the multilayer mask consists of at least two layers of materials having different etching rates;
removing the exposed dielectric layer, so as to form a trench;
over-etching the dielectric layer, so as to widen the inside diameter of the trench;
forming a conductive layer on the substrate, so as to cover the multilayer mask and a surface of the trench; and
removing the conductive layer except that in the trench, so as to form the electrode of the capacitor.

2. The method of fabricating the electrode of the capacitor as claimed in claim 1, wherein the step of forming the multilayer mask on the dielectric layer comprises:
forming a silicon nitride layer on the dielectric layer;
forming a polysilicon mask on the silicon nitride layer; and
transferring a pattern of the polysilicon mask to the silicon nitride layer.

3. The method of fabricating the electrode of the capacitor as claimed in claim 2, wherein the step of over-etching the dielectric layer comprises cleaning the residual polysilicon mask at the same time.

4. The method of fabricating the electrode of the capacitor as claimed in claim 1, wherein the process of over-etching the dielectric layer comprises wet etching.

5. The method of fabricating the electrode of the capacitor as claimed in claim 1, wherein the step of removing the conductive layer except that in the trench comprises:
filling a photoresist layer in the trench; and
etching back the conductive layer.

6. The method of fabricating the electrode of the capacitor as claimed in claim 5, after removing the conductive layer except that in the trench, further comprising removing the photoresist layer.

7. The method of fabricating the electrode of the capacitor as claimed in claim 1, wherein the material of the conductive layer is one selected from among polysilicon, hemi-spherical silicon grain (HSG), metal, and a nitride thereof.

8. A method of fabricating the capacitor, comprising:
providing a substrate having a contact;
forming a dielectric layer on the substrate;
forming a multilayer mask on the dielectric layer, and exposing a portion of the dielectric layer, wherein the multilayer mask consists of at least two layers of materials with different etching rates;
removing the exposed dielectric layer, so as to form a trench and expose the contact;
over-etching the dielectric layer, so as to widen the inside diameter of the trench, wherein the etching rate of the dielectric layer is higher than the etching rate of the multilayer mask;
forming a first electrode on the surface of the trench;
forming a capacitor dielectric layer on the first electrode; and
forming a second electrode on the capacitor dielectric layer.

9. The method of fabricating the capacitor as claimed in claim 8, wherein the step of forming the multilayer mask on the dielectric layer comprises:
forming a silicon nitride layer on the dielectric layer;
forming a polysilicon mask on the silicon nitride layer; and
transferring a pattern of the polysilicon mask to the silicon nitride layer.

10. The method of fabricating the capacitor as claimed in claim 9, wherein the step of over-etching the dielectric layer comprises cleaning the residual polysilicon mask at the same time.

11. The method of fabricating the capacitor as claimed in claim 8, wherein the process of over-etching the dielectric layer comprises wet etching.

12. The method of fabricating the capacitor as claimed in claim 8, wherein the step of forming the first electrode on the surface of the trench comprises:
forming a conductive layer on the substrate, so as to cover the multilayer mask and the surface of the trench;
filling a photoresist layer in the trench;
etching back the conductive layer; and
removing the photoresist layer.

13. The method of fabricating the capacitor as claimed in claim 8, wherein the contact is a storage node contact (SNC).

14. The method of fabricating the capacitor as claimed in claim 8, wherein the material of the first electrode is one selected from among polysilicon, HSG, metal, and a nitride thereof.

15. The method of fabricating the capacitor as claimed in claim 8, wherein the material of the capacitor dielectric layer comprises SiO₂, Si₃N₄, Ta₂O₅, HfO₂, HfON, ZrO₂, CeO₂, TiO₂, Y₂O₃, Al₂O₃, La₂O₅, SrTiO₃, BST, or PZT.

16. The method of fabricating the capacitor as claimed in claim 8, wherein the material of the second electrode is one selected from among polysilicon, AlCu, metal, and a nitride thereof.

17. The method of fabricating the capacitor as claimed in claim 8, after the capacitor dielectric layer is formed and before the second electrode is formed, further comprising forming an intermediate layer on a surface of the capacitor dielectric layer.

18. The method of fabricating the capacitor as claimed in claim 17, wherein the material of the intermediate layer is selected from a group consisting of TiN, TaN, Ti, and Ta.
